(19) United States
(12) Patent Application Publication
(10) Pub. No.: US 2008/0268143 A1
(43) Pub. Date: Oct. 30, 2008

(54) Device For Providing Vapors Of A Solid Precursor To A Processing Device

(76) Inventors: Constantin Vahlas, Toulouse (FR); Brigitte Caussat, Ramonville Saint Agne (FR); Francois Senocq, Toulouse (FR); Wayne L. Gladfelter, Roseville, MN (US)

Correspondence Address: Howard IP Law Group, P.O. Box 226, Fort Washington, PA, 19034, US

(21) Appl. No.: 11/792,020

(22) PCT Filed: Nov. 30, 2005
(86) PCT No.: PCT/EP2005/056358

§ 371 Date: Mar. 27, 2008

(30) Foreign Application Priority Data
Nov. 30, 2004 (FR) 0452817

(51) Int. Cl. B05D 1/24; C23C 16/00

(52) U.S. Cl. 427/185; 118/733

(57) ABSTRACT

The present invention relates to a device for providing vapors of at least one solid precursor intended to supply a physico-chemical processing device, comprising an enclosure capable of containing particles of the solid precursor and comprising an inlet and an outlet, the outlet being intended to be connected to the physico-chemical processing device; and means for circulating a gas between the inlet and the outlet to put the particles of the solid precursor in the form of a fluidized bed, and to convey to the outlet vapors of the solid precursor.

### FIELD OF THE INVENTION

The present invention relates to a device for providing vapors of a solid precursor for the supply of a physico-chemical processing device, for example, a surface-processing device, a thin or coating layer deposition device, or a powder manufacturing device. Such a processing device is, for example, a chemical vapor deposition device.

### BACKGROUND OF THE INVENTION

A physico-chemical processing device of chemical vapor deposition device type requires being constantly supplied in reproducible fashion with vapors of a precursor or of several precursors. Many inorganic or organometallic compounds would be likely to be used as precursors for processing devices of chemical vapor deposition device type. However, such compounds appear, most frequently, in solid form, and a major difficulty then is to obtain vapors of such compounds in a way that would be compatible with the operation of such processing devices.

A first method for providing vapors of a solid precursor comprises the dissolving of the precursor. An evaporation chamber then enables evaporating the obtained solution. The main disadvantage of such a method is the use of solvents to transport the precursor. Indeed, unwanted reactions risk occurring between the solvent and the precursor. The presence of the solvent in liquid form or as a precursor in condensed form in the processing device must imperatively be avoided to prevent any contamination. A possibility to get rid of the solvent is to decompose it, which may be difficult to implement according to the operation performed by the processing device. Further, the handling of solvents generally is a delicate operation, in particular due to the risk of the presence of effluents, and requires specific precautions making such a device for providing solid precursor vapors particularly complex.

According to a method for providing solid precursor vapors, the precursor is not dissolved in a solvent. This provides a system potentially devoid of impurities, since no external substances are introduced into the processing device. In such a solid precursor vapor provision device, the vapors are obtained by sublimation of the solid precursor in a chamber generally independent from the processing device, the transportation of the solid precursor vapors to the processing device being performed via a carrier gas.

FIG. 1 shows a conventional example of a device 10 for providing vapors of a solid precursor to a physico-chemical processing device 12, for example, a chemical vapor deposition device, implementing the second previously-described solid precursor vapor provision method. Device 10 comprises an external cylindrical enclosure 14 containing an internal cylindrical enclosure 16 in which solid precursor 17 is placed. Means 18 for supplying a carrier gas, for example, nitrogen, are connected at the level of the upper part of internal enclosure 16 and supplies internal enclosure 16 with a carrier gas. The bottom of internal enclosure 16 is formed of a porous wall 20 capable of retaining the solid precursor but of letting through the gas compounds. Solid precursor 17 is maintained at a constant temperature at which it sublimates. On operation of such a device 10, the carrier gas crosses solid precursor 17 and enriches with vapors of the sublimated solid precursor. The enriched carrier gas then passes through porous 20 in the space provided between external enclosure 14 and enclosure 16. It is then collected and conveyed to processing device 12 by a duct 22. Processing device 12 comprises a gas outlet, not shown.

With such a device for providing solid precursor vapors, a decrease along time in the precursor vapor flow rate can however be observed due, in particular, to the following phenomena:

progressive decrease in the surface area of the solid precursor where the sublimation occurs; and

forming of channels in the solid precursor in which the carrier gas flows in privileged fashion and which limit the contact with the solid precursor.

Further, since the variation of the exchange surface area between the solid precursor and the carrier gas is difficult to control, it is difficult to ensure a vapor-forming flow rate reproducible on successive uses of the device for providing solid precursor vapors.

Another difficulty results from the fact that, to obtain a sufficient amount of vapors, the solid precursor must be maintained at a high temperature for the entire vapor forming phase, which may sometimes cause problems of decomposition of the solid precursor in the vapor provision device. Further, the vapors of the solid precursor being obtained at a high temperature, it is necessary to provide means capable of heating duct 22 to avoid a condensation of the vapors during the transportation to the processing device, which may result to be difficult.

### SUMMARY OF THE INVENTION

An object of the invention is to obtain a device for providing vapors of a solid precursor by sublimation of the pre-cursor enabling substantially constant and reproducible provision of vapors of the solid precursor to a physico-chemical processing device.

Another object of the present invention is to provide a device for providing vapors of a solid precursor to a physico-chemical processing device enabling limiting the decomposition of the solid precursor in the device.

Another object of the present invention is to provide a device for providing vapors of a solid precursor to a physico-chemical processing device of relatively simple design and maintenance.

To achieve these objects, the present invention provides a device for providing vapors of at least one solid precursor intended to supply a physico-chemical processing device, comprising an enclosure capable of containing particles of the solid precursor and comprising an inlet and an outlet, the outlet being intended to be connected to the physico-chemical processing device; and means for circulating a gas between the inlet and the outlet to put the particles of the solid precursor in the form of a fluidized bed, and to convey to the outlet vapors of the solid precursor.

According to another embodiment of the invention, the device further comprises a duct connected to the outlet and intended to be connected to the physico-chemical processing device; and a filter, at the level of the duct and/or at the level of the outlet, capable of trapping the particles of the solid precursor carried along by the gas enriched with vapors of the solid precursor.

According to another embodiment of the invention, the device comprises means for heating the inner volume of the enclosure.

According to another embodiment of the invention, the device comprises a grid in the enclosure between the inlet and the inner volume of the enclosure capable of receiving the solid precursor particles.

According to another embodiment of the invention, the means for circulating the gas comprise gas provision means; a duct connecting the gas provision means to the enclosure; and means for controlling the gas flow running through the duct.

The present invention also provides a physico-chemical processing system comprising a device for providing vapors of at least one solid precursor and a physico-chemical processing device receiving said vapors. The provision device comprises an enclosure capable of containing particles of the solid precursor and comprising an inlet and an outlet, the outlet being connected to the physico-chemical processing device; and means for circulating a gas between the inlet and the outlet to put the particles of the solid precursor in the form of a fluidized bed, and to carry towards the outlet vapors of the solid precursor.

According to another embodiment of the invention, the physico-chemical processing device is a chemical vapor deposition device.

The present invention also provides a method for providing vapors of at least one solid precursor to a physico-chemical processing device, comprising the steps of arranging particles of the solid precursor in an enclosure comprising an inlet and an outlet, the outlet being connected to the physico-chemical processing device; circulating a gas in the enclosure to put the particles of the solid precursor in the form of a fluidized bed; and providing the physico-chemical processing device with the gas exhausted through the outlet enriched with vapors of the solid precursor.

According to another embodiment of the invention, the solid precursor particles are mixed with particles of an inert solid compound capable of favoring the forming of the fluidized bed.

According to another embodiment of the invention, the gas is an inert or reactive gas.

According to another embodiment of the invention, the internal volume of the enclosure is maintained at a temperature lower than 300° C.

According to another embodiment of the invention, the average pressure at the level of the outlet is greater than 1,000 Pa.

### BRIEF DESCRIPTION OF THE DRAWINGS

The foregoing and other objects, features, and advantages of the present invention will be discussed in detail in the following non-limiting description of specific embodiments in connection with the accompanying drawings, among which:

FIG. 1, previously described, shows a conventional device for providing vapors of a solid precursor to a physico-chemical processing device;

FIG. 2 shows a first example of the forming according to the present invention of a device for providing vapors of a solid precursor to a physico-chemical processing device;

FIG. 3 illustrates the operating principle of the device for providing vapors of a solid precursor of FIG. 2;

FIG. 4 shows a second example of the forming according to the invention of a device for providing vapors of a solid precursor; and

FIG. 5 shows the optimal variation of the flow rate of the precursor provided according to the vector gas flow rate and the variation obtained for a conventional device for providing vapors of a solid precursor and the second example of forming of the vapor provision device according to the invention.

For clarity, same elements have been designated with same reference numerals in the different drawings.

### DETAILED DESCRIPTION

The present invention comprises the provision of a device for providing vapors of a solid precursor in which, in operation, the solid precursor is put in the form of a fluidized bed of particles of the solid precursor. The forming of the fluidized bed is obtained by means of a fluidization gas, which is also used as a gas for conveying the solid precursor vapors to the physico-chemical processing device connected to the device according to the invention.

FIG. 2 shows a first example of the forming of a device for providing solid precursor vapors 30 according to the invention. Device 30 comprises an external enclosure 32 comprising an opening 34 in its upper portion and an opening 36 in its lower portion. A grid 38 is arranged at the level of the lower portion of enclosure 32. Solid particles of a precursor are arranged on grid 38 in the form of a fixed layer 40. The solid precursor powder is defined by an average diameter of solid precursor particles and by a dispersion of the diameter around the average diameter. Grid 38 is selected to forbid the passing of particles of the solid precursor.

Means 42 for supplying a fluidization gas are connected to opening 36 of device 30 by a supply duct 43 and provide the fluidization gas with a mass flow rate controlled by a mass flow controller 44. As an example, the fluidization gas is an inert gas which does not react with the solid precursor, for example, nitrogen. Opening 36 enables connecting device 30 according to the invention to physico-chemical processing device 12 via duct 22. A filter 46 is provided at the level of duct 22. A pressure sensor 48 enables determining the pressure loss of the fluidization gas between openings 36 and 34. According to a variation of the present invention, filter 46 is arranged at the level of opening 36.

A heating system 50, comprising, for example, a set of resistors surrounding enclosure 32, enables setting the temperature in enclosure 32. A temperature sensor 52, for example formed of one or several thermocouples arranged at different levels in enclosure 32, provides a signal representative of the temperature in enclosure 32 to a control unit 54 capable of controlling heating system 50. Further, the fluidization gas crossing supply duct 43 is also heated before its admission in enclosure 32. Such a heating may be obtained by means of a set of electric resistors, in the form of coils, surrounding supply duct 43.

FIG. 3 illustrates the operation of device 30 of FIG. 2. When device 30 is supplied with the fluidization gas, the fluidization gas crosses the internal volume of enclosure 32, substantially according to an upward direction, from opening 34 to opening 36. For small speeds of the fluidization gas, layer 40 of particles of the solid precursor remains at the level of gate 38 with no visible motions. When the speed of the fluidization gas crossing the internal volume of enclosure 32 is greater than a minimum speed, a putting in suspension of the particles of the solid precursor can be observed. A fluidized bed 56 having a height H which increases along with the speed of the fluidization gas crossing device 30 is thus formed. Height H can thus be controlled via mass flow controller 44. In fluidized bed 56, the solid precursor particles are substantially independent from one another and are submitted to random motions of small amplitude. However, no general translation motion of fluidized bed 56 can be observed. The upper surface of fluidized bed 56 is practically neat and horizontal. From a given speed of the fluidization gas, heterogeneities appear in fluidized bed 56 with bubbling phenomena corresponding to the forming, in fluidized bed 56, of cavities which grow and rise to the surface of fluidized bed 56. The surface aspect of fluidized bed 56 then is that of a boiling liquid. When the fluidization gas speed exceeds a maximum speed, all or at least most of the particles of fluidized bed 56 are driven outside of enclosure 32. The speed of the fluidization gas must thus be maintained between the minimum and maximum speeds.

The average pressure prevailing in enclosure 32 must be sufficient to enable forming of a fluidized bed. This is why the average pressure of operation of device 30 according to the present invention is, at the level of opening 36, preferably greater than approximately 1,333 Pa (10 Torr) and can rise up to the atmospheric pressure. The determination of the real speed of the fluidization gas in enclosure 32 enables controlling that fluidized bed 56 has properly formed. The real speed of the fluidization gas may be determined from the mass flow rate of the fluidization gas imposed by mass flow controller 44, from the cross-section of fluidized bed 56, from the pressure and from the temperature of fluidized bed 56. In practice, on operation of the device according to the invention, the measurement of the pressure loss between the inlet and the outlet of device 30 provided by pressure sensor 48 enables directly controlling the good fluidization state of the solid precursor. Filter 46 enables avoiding for particles of fluidized bed 56 having a smaller diameter than the average particle diameter to be carried along by fluidization gas in duct 22 and to reach processing device 12, even when the fluidization gas speed is maintained between the minimum and maximum speeds.

On operation of the device according to the first example of embodiment, the temperature in enclosure 32 is maintained at a substantially constant temperature capable of enabling sufficient sublimation of the particles of the solid precursor of fluidized bed 56. The sublimation speed of a solid precursor particle is substantially proportional to the exchange surface area between the particle and the gas surrounding it and is substantially proportional to the difference between the vapor tension of the solid precursor and the partial and local pressure of the vapor having already spread around the particle. The vapors thus freed are immediately carried by fluidization gas to processing device 12. The implementation of a fluidized bed 56 enables optimizing precursor-gas exchanges, since each particle of fluidized bed 56 is in contact with the fluidization gas on its entire outer surface.

The solid precursor particles may be mixed with particles of a chemically and physically inert compound, for example, corundum or silica. This enables controlling the forming rate of solid precursor vapors by controlling of the total exchange surface area between the solid precursor particles and the fluidization gas. Further, the inert compound powder is selected to ease the forming of fluidized bed 56, especially by the use of a powder formed of particles having well-mastered shapes and dimensions and/or by the use of a powder having particles which do not tend to link to one another. The use of inert particles mixed with the particles of the solid precursor especially enables easing the forming of a fluidized bed in cases where the use of the solid precursor alone would make the obtaining of a fluidized bed difficult. Such is the case, for example, when the solid precursor appears in the from of a powder of sticky particles or of a powder formed of a particles having very irregular shapes.

As an example, in the case where processing device 12 performs a chemical vapor deposition of an alumina layer on a substrate, the solid precursor may be aluminum-acetyl-acetonate ((CH₃CO)₂CH)₃Al. The fluidization gas may then be nitrogen. As an example, the average particle diameter is approximately 35 μm, with a dispersion ranging from a 2-μm to 70-μm diameter. To optimize the forming of the fluidized bed, such a precursor may be mixed with an alumina powder of substantially spherical particles having an average diameter of approximately 350 μm, with a dispersion ranging from a 100-μm to a 600-μm diameter. The solid precursor proportion amounts, for example, to approximately 10% of the total mass of the particles forming fluidized bed 56. The used sublimation temperature is, as an example, on the order of 120° C. The nitrogen gas flow rate may be on the order of from 3,000 to 8,000 cm³ per minute in the standard state.

The present invention has enabled showing that the fluidization gas range adapted to the forming of a fluidized bed is compatible with the supply flow rates required by processing devices of chemical vapor deposition type.

The present invention has many advantages:

First, it enables obtaining a substantially constant flow rate of vapors of a solid precursor in a phase of operation of the device according to the invention. Indeed, each precursor particle contained in the fluidized bed takes part in the forming of vapors. The decrease in the dimensions of each particle and, accordingly, the decrease in the total precursor-fluidization gas exchange surface area is thus very slow in a phase of operation of the device according to the invention. Further, it is always possible, if necessary, to add particles of the solid precursor in enclosure 32 during the operation of the device according to the invention. The device according to the invention can thus be used to provide vapors of a solid precursor in continuous fashion.

Second, the provision of vapors of the solid precursor can be performed in reproducible fashion. Indeed, the implementation of fluidized bed 56 enables accurately controlling the total precursor-gas exchange surface area on sublimation of the solid precursor. Indeed, the stirring of the particles of fluidized bed 56 especially enables avoiding, with respect to a conventional sublimation device, the forming, in the solid precursor, of preferential flow channels of the carrier gas causing a significant variation in the total precursor-gas exchange surface area along time. Since fluidized bed 56 can be formed in reproducible fashion, device 30 according to the invention ensures the obtaining of a substantially identical total precursor-gas exchange surface area for fluidized beds of same compositions and of same features, which enables provision of the same quantity of precursor vapors on each use of device 30 in the same conditions.

Third, the total precursor-gas exchange surface area is clearly increased with respect to a conventional sublimation device. The total precursor-gas exchange surface area is besides substantially optimal, since each solid precursor particle of fluidized bed 56 is in contact with the fluidization gas on its entire outer surface area. The efficiency of the sublimation is thus optimal. The obtained flow rate of vapors of the solid precursor is then practically proportional to the fluidization gas flow rate. Further, for a same amount of vapors to be obtained, the vapor tension of the solid precursor to be provided can be decreased as compared with a conventional sublimation device. This enables decreasing the temperature of the solid precursor with respect to that generally used in a conventional sublimation device. The enclosure temperature is maintained under 300° C., preferably below 250° C. The temperature decrease of the solid precursor enables limiting risks of decomposition of the solid precursor. This further also enables heating duct 22 connecting device 30 according to the invention to processing device 12 at temperatures lower than those currently used.

Fourth, fluidized bed 56 causes a stirring of the particles of the solid precursor and thus enables good homogenization of the temperatures of the particles in enclosure 32. Any forming of hot spots in enclosure 32 likely to favor an unwanted decomposition of the solid precursor and a poor control of the sublimation is thus avoided.

Fifth, the device according to the present invention is of particularly simple design and maintenance since it essentially only requires regular cleaning of filter 46 for trapping the solid precursor particles.

In the described example, a single solid precursor has been used. The forming of a fluidized bed formed of particles of different solid precursors may however be envisaged according to the operation to be performed by processing device 12 which receives the solid precursor vapors. The supply of a same processing device with vapors of different solid precursors provided by several vapor provision devices according to the present invention may also be provided.

In the previously-described example, the fluidization gas is an inert gas only used for the forming of fluidized bed 56 and for the transport of the solid precursor vapors to processing device 12. A gas or a gas mixture reacting at least partially with the solid precursor may however be used as a fluidization gas. As an example, water vapor may be added to the nitrogen, which generally causes the forming, in the obtained vapors, of intermediary gaseous compounds which are more reactive for chemical vapor deposition reactions. As an example, for a precursor formed of aluminum pellets, HCl gas may be added to the nitrogen to form vapors of aluminum trichloride type or of another gaseous aluminum halogenide used for a chemical vapor deposition.

According to a variation of the present invention, enclosure 32 comprises baffles arranged above fluidized bed 56, or any other adapted mechanical system, enabling limiting the carrying off of particles of fluidized bed 56 by the fluidization gas in duct 22.

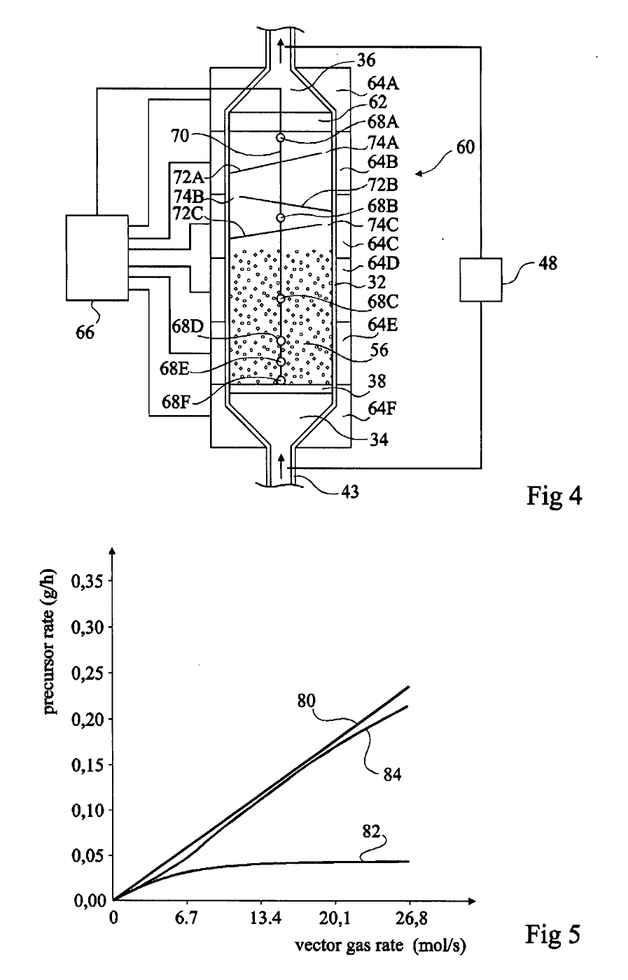

FIG. 4 shows a second example of the forming of a device 60 for providing vapors of a solid precursor according to the invention. The elements common with the first example of embodiment will not be described again. As an example, the height of enclosure 32 is 110 centimeters and the internal diameter of enclosure 32 is 5 centimeters. A filter 62 is arranged at the level of outlet 36 of enclosure 32. It is for example a filter, the openings of which have a 5-micrometer average diameter.

The heating of enclosure 32 is performed by six distinct heater bands 64A to 64F. A control unit 66 is connected to heater bands 64A to 64F and is capable of separately controlling the amount of heat provided by each heater band. Six temperature sensors 68A to 68F are arranged in enclosure 32 on a shaft 70 arranged substantially at the level of the axis of symmetry of enclosure 32. The signals provided by temperature sensors 68A to 68F are provided to control unit 50. The second example of embodiment enables independently regulating the temperature of each portion of enclosure 32 surrounded by a heater band 64A and 64F according to the signals provided by temperature sensors 68A to 68F. In FIG. 4, temperature sensors 68A to 68F are not regularly distributed in enclosure 32, but are concentrated towards the base of enclosure 32 where it can be desirable to know the temperature variation with a greater accuracy. According to a variation, each temperature sensor 68A to 68F may be arranged in enclosure 32 at the level of a heater band 64A to 64F. Control unit 60 can then directly control the amount of heat provided by each heater band 64A to 64F based on the signal provided by the associated temperature sensor 68A to 68F.

Three chicanes 72A, 72B, 72C are arranged in enclosure 32. Chicanes 72A, 72B, 72C correspond, for example, to planar plates attached to shaft 70 and which are inclined with respect to shaft 70. Each chicane 72A, 72B, 72C practically completely closes the way into enclosure 32 to only leave an opening 74A, 74B, 74C at the level of the wall of enclosure 32. The inclination of plates 72A, 72B, 72C and the position of openings 74A, 74B, 74C are alternated to limit the escape of particles from fluidized bed 56 without obstructing the way of the precursor vapors. The chicane 72A closest to opening 34 is arranged in enclosure 32 to be above the upper surface of fluidized bed 56 when said bed is in a stationary state.

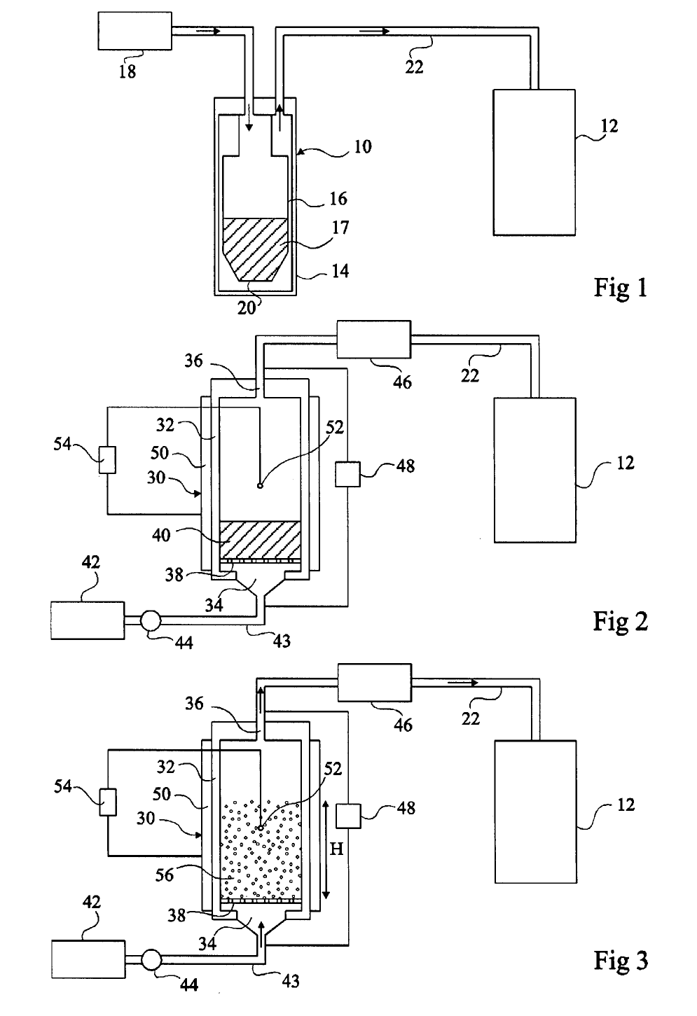

FIG. 5 shows the variation of the precursor flow rate provided according to the vector gas flow rate. Variation curve 80 corresponds to the maximum flow rate that can be obtained. Variation curve 82 is obtained with a conventional device for providing vapors of a solid precursor, for example, the device of FIG. 1, and variation curve 84 is obtained with provision device 60. The curves have been obtained by using aluminum acetyl acetonate as a precursor and nitrogen as a vector gas. It should be noted that, for the conventional device, curve 82 considerably differs from the maximum flow rate when the nitrogen flow rate increases. The efficiency obtained with device 60 is very close to the maximum efficiency. It should be noted that for very low nitrogen flow rates, curves 82 and 84 are confounded. This corresponds to the case where the nitrogen flow rate is too low to enable obtaining of a fluidized bed in device 60 which then operates as a conventional device.

Of course, the present invention is likely to have various alterations, modifications, and improvements which will occur to those skilled in the art. In particular, the device according to the invention has been described for the forming of a fluidized bed by an ascending motion of the fluidization gas. However, the device according to the invention can be implemented for the forming of a “rotating fluidized bed”. In this case, as in the previous case, fluidization gas is injected according to an ascending motion to form the fluidized bed. However, fluidization gas is further injected at the level of the lateral walls of enclosure 32, causing a general rotating motion of the fluidized bed around a substantially vertical axis. Further, the device according to the present invention may be implemented for the forming of a “circulating fluidized bed” or “ascending fluidized bed” in which the speed of the fluidization gas is sufficiently high to carry along part of the particles of the fluidized bed outside of enclosure 32, the ejected particles being collected and injected back into the fluidized bed.

1. A device for providing vapors of at least one solid precursor intended to supply a physico-chemical processing device, comprising:
an enclosure capable of containing particles of the solid precursor and comprising an inlet and an outlet, the outlet being intended to be connected to the physico-chemical processing device; and
means for circulating a gas between the inlet and the outlet to put the particles of the solid precursor in the form of a fluidized bed, and to convey to the outlet vapors of the solid precursor.

2. The device of claim 1, further comprising:
a duct connected to the outlet and intended to be connected to the physico-chemical processing device; and
filter, at the level of the duct and/or at the level of the outlet, capable of trapping the particles of the solid precursor carried along by the gas enriched with vapors of the solid precursor.

3. The device of claim 1, comprising means for heating the inner volume of the enclosure.

4. The device of claim 1, comprising a grid in the enclosure between the inlet and the inner volume of the enclosure capable of receiving the solid precursor particles.

5. The device of claim 1, in which the means for circulating the gas comprise:
gas provision means;
a duct connecting the gas provision means to the enclosure; and
means for controlling the gas flow running through the duct.

6. A physico-chemical processing system comprising a device for providing vapors of at least one solid precursor and a physico-chemical processing device receiving said vapors, characterized in that said device comprises:
an enclosure capable of containing particles of the solid precursor and comprising an inlet and an outlet, the outlet being connected to the physico-chemical processing device; and
means for circulating a gas between the inlet and the outlet to put the particles of the solid precursor in the form of a fluidized bed, and to carry towards the outlet vapors of the solid precursor.

7. The system of claim 6, in which the physico-chemical processing device is a chemical vapor deposition device.

8. A method for providing vapors of at least one solid precursor to a physico-chemical processing device, comprising the steps of:
arranging particles of the solid precursor in an enclosure comprising an inlet and an outlet, the outlet being connected to the physico-chemical processing device;
circulating a gas in the enclosure to put the particles of the solid precursor in the form of a fluidized bed; and
providing the physico-chemical processing device with the gas exhausted through the outlet enriched with vapors of the solid precursor.

9. The method of claim 8, in which the solid precursor particles are mixed with particles of an inert solid compound capable of favoring the forming of the fluidized bed.

10. The method of claim 8, in which the gas is an inert gas.

11. The method of claim 8, in which the internal volume of the enclosure is maintained at a temperature lower than 250° C.

12. The method of claim 8, in which the average pressure at the level of the outlet is greater than 1,000 Pa.
